(19) United States
(12) Patent Application Publication
(10) Pub. No.: US 2024/0234440 A1
(43) Pub. Date: Jul. 11, 2024

(54) PREPARATION METHOD FOR ARRAY SUBSTRATE AND PREPARATION METHOD FOR DISPLAY PANEL

(71) Applicants: Fuzhou BOE Optoelectronics Technology Co., Ltd., Fuzhou, Fujian (CN); BOE Technology Group Co., Ltd., Beijing (CN)

(72) Inventors: Bin LIN, Beijing (CN); Yang WANG, Beijing (CN); Liangliang LI, Beijing (CN); Zengrong LI, Beijing (CN); Hangle GUO, Beijing (CN); Wenxing XI, Beijing (CN)

(21) Appl. No.: 18/558,740

(22) PCT Filed: Jul. 1, 2022
(86) PCT No.: PCT/CN2022/103344

§ 371 Date: Nov. 2, 2023

(30) Foreign Application Priority Data
Jul. 19, 2021 (CN) 202110811863.7

(51) Int. Cl. H01L 27/12

(52) U.S. Cl. CPC H01L 27/124; H01L 27/127

(57) ABSTRACT

Disclosed is a preparation method for an array substrate including: forming a first conductive portion on a substrate; sequentially forming a first insulating layer, a second insulating layer and a third insulating layer on the side of the first conductive portion that faces away from the substrate; forming, through one-time patterning process, a first sub-via that penetrates through the third insulating layer, the second insulating layer and a first part of the first insulating layer; forming a fourth insulating layer on the side of the third insulating layer that faces away from the substrate; etching and removing the fourth insulating layer and the first insulating layer of the second thickness that are at the first sub-via, so as to form a first via; and forming a first connection electrode on the side of the fourth insulating layer that faces away from the substrate.

### CROSS-REFERENCE TO RELATED APPLICATIONS

The present application is a U.S. National Phase Entry of International Application No. PCT/CN2022/103344 having an international filing date of Jul. 1, 2022, which claims priority to Chinese Patent Application No. 202110811863.7, filed to the CNIPA on Jul. 19, 2021. The entire contents of the above-identified applications are hereby incorporated by reference.

### TECHNICAL FIELD

The present disclosure belongs to the field of display technologies, in particular to a preparation method of an array substrate and a preparation method of a display panel.

### BACKGROUND

In recent years, with more and more extensive application of liquid crystal display products, liquid crystal display technologies are becoming more and more mature. A Thin Film Transistor-Liquid Crystal Display (TFT-LCD) occupies a very important position in the display field with its high-quality image display, low energy consumption, environmental protection, and other advantages.

For a liquid crystal display, quality of an array substrate is very important. In a process of preparing the array substrate, it is necessary to deposit an insulation layer on the array substrate, and etch the insulation layer by using an etching process to form a via, so as to achieve an electrical connection of metal layers in different layers.

### SUMMARY

The present disclosure aims at solving at least one of technical problems existing in the prior art, to provide a preparation method of an array substrate and a preparation method of a display panel.

In a first aspect, an embodiment of the present disclosure provides a preparation method of an array substrate, including following acts: forming a first conductive portion on a base substrate; forming a first insulation layer on a side of the first conductive portion that faces away from the base substrate, forming a second insulation layer on a side of the first insulation layer that faces away from the base substrate, and forming a third insulation layer on a side of the second insulation layer that faces away from the base substrate; forming, through one-time patterning process, a first sub-via that penetrates through the third insulation layer, the second insulation layer, and a first part of the first insulation layer, wherein the first part of the first insulation layer has a first thickness; an orthographic projection of the first sub-via on the base substrate is at least partially overlapped with an orthographic projection of the first conductive portion on the base substrate, and a thickness of remaining first insulation layer at a position of the first sub-via is a second thickness; forming a fourth insulation layer on a side of the third insulation layer that faces away from the base substrate; etching and removing the fourth insulation layer and the first insulation layer with the second thickness that are at the first sub-via to form a first via, wherein the first via exposes the first conductive portion; and forming a first connection electrode on a side of the fourth insulation layer that faces away from the base substrate, wherein the first connection electrode is electrically connected with the first conductive portion through the first via.

Optionally, the act of forming, through one-time patterning process, the first sub-via that penetrates through the third insulation layer, the second insulation layer, and the first part of the first insulation layer specifically includes: forming, through one-time patterning process, a groove penetrating through the third insulation layer, wherein an orthographic projection of the groove on the base substrate is at least partially overlapped with the orthographic projection of the first conductive portion on the base substrate; and etching and removing the second insulation layer and the first insulation layer with the first thickness at a position of the groove to obtain a first sub-via, wherein the orthographic projection of the groove on the base substrate covers the orthographic projection of the first sub-via on the base substrate, and the thickness of the remaining first insulation layer at the position of the first sub-via is the second thickness.

Optionally, the act of forming the first insulation layer on the side of the first conductive portion that faces away from the base substrate specifically includes: forming a second sub-insulation layer having the second thickness on a side of the first conductive portion that faces away from the base substrate; and forming a first sub-insulation layer having the first thickness on a side of the first sub-insulation layer that faces away from the base substrate; the act of etching and removing the second insulation layer and the first insulation layer with the first thickness at the position of the groove to obtain the first sub-via specifically includes: etching and removing the second insulation layer and the first sub-insulation layer at the position of the groove to obtain the first sub-via; and the act of etching and removing the fourth insulation layer and the first insulation layer with the second thickness at the first sub-via to form the first via includes: etching and removing the fourth insulation layer and the second sub-insulation layer at the first sub-via to form the first via.

Optionally, a material of the first sub-insulation layer includes silicon oxide, and materials of the second sub-insulation layer and the fourth insulation layer include silicon nitride.

Optionally, between the act of forming the first insulation layer and the act of forming the second insulation layer, the method further includes: forming a second conductive portion on a side of the first sub-insulation layer that faces away from the base substrate; forming, through one-time patterning process, the groove on the third insulation layer, wherein the orthographic projection of the groove on the base substrate is further at least partially overlapped with an orthographic projection of the second conductive portion on the base substrate; and etching and removing the second insulation layer and the first sub-insulation layer at the position of the groove to obtain a second sub-via; after the act of forming the fourth insulation layer on the side of the third insulation layer that faces away from the base substrate, the method further includes: etching and removing the fourth insulation layer and the second sub-insulation layer at the second sub-via to form a second via, wherein the second via exposes the second conductive portion; and forming a first connection electrode on a side of the fourth insulation layer that faces away from the base substrate, wherein the first connection electrode is further electrically connected with the second conductive portion through the second via.

Optionally, the array substrate includes a display region and a peripheral region surrounding the display region, the peripheral region is provided with a gate drive circuit, the gate drive circuit includes shift registers, each shift register includes a plurality of thin film transistors, the plurality of thin film transistors at least include a pull-down control transistor, a gate of the pull-down control transistor is electrically connected with a source; wherein the first conductive portion is the gate of the pull-down control transistor, and the second conductive portion is the source of the pull-down control transistor.

Optionally, the array substrate includes a display region and a peripheral region surrounding the display region, the array substrate further includes a gate line extending from the display region to the peripheral region, the peripheral region is provided with a gate drive circuit, the gate drive circuit includes a plurality of shift registers, each shift register includes a plurality of thin film transistors, the plurality of thin film transistors at least include an output transistor, a drain of the output transistor is connected with a signal output terminal, and the signal output terminal is connected with the gate line; wherein the first conductive portion is the gate line, and the second conductive portion is the signal output terminal.

Optionally, the array substrate includes a plurality of gate lines and a plurality of data lines which are disposed in a cross way, and a plurality of sub-pixels, wherein a sub-pixel includes a thin film transistor, a pixel electrode, and a common electrode; the gate line and a gate of the thin film transistor are also formed while the first conductive portion is formed; and the common electrode is also formed while the first connection electrode is formed.

Optionally, the array substrate further includes a common electrode line, and the first conductive portion serves as the common electrode line.

Optionally, the preparation method of the array substrate further includes: further forming a third conductive portion on a side of the first sub-insulation layer that faces away from the base substrate; further forming, through one-time patterning process, a third sub-via on the third insulation layer, wherein an orthographic projection of the third sub-via on the base substrate is further at least partially overlapped with an orthographic projection of the third conductive portion on the base substrate; etching and removing the second insulation layer within the third sub-via to form a third via; and forming a second connection electrode layer on a side of the fourth insulation layer that faces away from the base substrate, and forming a second connection electrode through a patterning process, wherein the second connection electrode is electrically connected with the third conductive portion through the third via.

Optionally, the act of etching and removing the second insulation layer and the first sub-insulation layer at the position of the first sub-via to obtain the second sub-via specifically includes: etching and removing the second insulation layer and the first sub-insulation layer that are at the position of the first sub-via through dry etching to obtain the second sub-via.

Optionally, a gas used for the dry etching includes NF3 and O2.

Optionally, the act of etching and removing the fourth insulation layer and the second sub-insulation layer at the second sub-via to form the first via specifically includes: etching and removing the fourth insulation layer and the second sub-insulation layer at the second sub-via through dry etching to form the first via, wherein an etching gas includes SF₆ and O₂.

In a second aspect, an embodiment of the present disclosure provides a preparation method of a display panel, including the preparation method of the array substrate as described above.

### BRIEF DESCRIPTION OF DRAWINGS

FIG. 1 is a schematic diagram of a structure of an exemplary array substrate.

FIG. 2 is a schematic diagram of a structure of another exemplary array substrate.

FIG. 3 is a process flowchart of a preparation method of an array substrate according to an embodiment of the present disclosure.

FIGS. 4a to 4f are schematic diagrams of a structure of an array substrate in each act of the process flowchart shown in FIG. 3.

FIG. 5 is a flowchart of specific acts of an act S103 in FIG. 3.

FIGS. 6a to 6b are schematic diagrams of a structure of an array substrate corresponding to the flowchart shown in FIG. 5.

FIG. 7 is a process flowchart of another preparation method of an array substrate according to an embodiment of the present disclosure.

FIGS. 8a to 8g are schematic diagrams of a structure of an array substrate in each act of the process flowchart shown in FIG. 7.

FIG. 9 is a process flowchart of yet another preparation method of an array substrate according to an embodiment of the present disclosure.

FIGS. 10a to 10g are schematic diagrams of a structure of an array substrate in each act of the process flowchart shown in FIG. 9.

FIG. 11 is a schematic diagram of a structure of an array substrate.

FIG. 12 is a circuit diagram of a shift register.

### DETAILED DESCRIPTION

To enable those skilled in the art to better understand technical solutions of the present disclosure, the present disclosure is described in further detail below in conjunction with the accompanying drawings and specific implementation modes.

Unless otherwise defined, technical terms or scientific terms used in the present disclosure should have ordinary meanings as understood by people with ordinary skills in the field to which the present disclosure belongs. “First”, “second”, and similar words used in the present disclosure do not indicate any order, quantity, or importance, but are only used for distinguishing different components. Similarly, a similar word such as “a”, “an”, or “the” does not denote a limitation on quantity, but rather denotes presence of at least one. “Include”, “contain”, or a similar word means that an element or object appearing before the word covers an element or object listed after the word and their equivalents, but does not exclude other elements or objects. “Connect”, “join”, or a similar word is not limited to a physical or mechanical connection, but may include an electrical connection, whether direct or indirect. “Upper”, “lower”, “left”, and “right”, etc., are only used for representing a relative positional relationship, and when an absolute position of a described object is changed, the relative positional relationship may also be correspondingly changed.

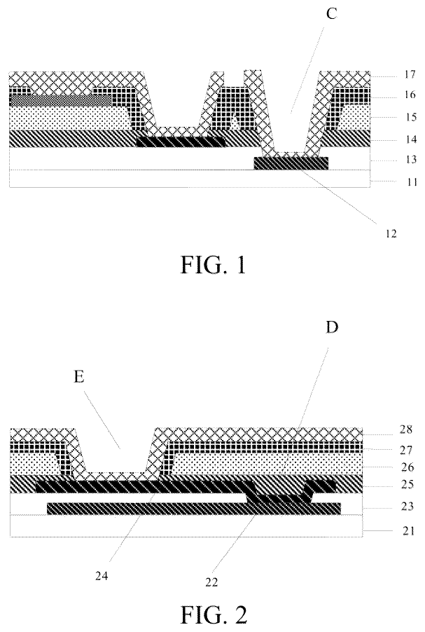

FIG. 1 is a schematic diagram of a structure of an exemplary array substrate. As shown in FIG. 1, the array substrate includes a common electrode line 12, a first insulation layer 13, a second insulation layer 14, a third insulation layer 15, a fourth insulation layer 16, and a connection electrode 17 which are stacked on a base substrate 11. The common electrode line 12 is disposed on the base substrate 11, the first insulation layer 13 is disposed on a side of the common electrode line 12 that faces away from the base substrate 11, the second insulation layer 14 is disposed on a side of the first insulation layer 13 that faces away from the base substrate 11, the third insulation layer 15 is disposed on a side of the second insulation layer 14 that faces away from the base substrate 11, the fourth insulation layer 16 is disposed on a side of the third insulation layer 15 that faces away from the base substrate 11, and the connection electrode 17 is disposed on a side of the fourth insulation layer 16 that faces away from the base substrate 11. The connection electrode 17 is connected with the common electrode line 12 through a via C that penetrates through the first insulation layer 13, the second insulation layer 14, the third insulation layer 15, and the fourth insulation layer 16.

A method of forming the via C of the array substrate shown in FIG. 1 generally includes: forming the common electrode line 12 on the base substrate 11 through a patterning process; sequentially forming the first insulation layer 13, the second insulation layer 14, the third insulation layer 15, and the fourth insulation layer 16 on the common electrode line 12; and etching and removing the fourth insulation layer 16, the third insulation layer 15, the second insulation layer 14, and the first insulation layer 13 in one act through an etching process, to obtain the via C.

The method of forming the via C has problems of a deep etching depth and long etching time because four insulation layers are etched and removed through one-act etching. Longer etching time will increase a polymer within the via, which will affect subsequent lapping of a metal within the via adversely, and further affect a product yield and quality of a display apparatus adversely.

FIG. 2 is a schematic diagram of a structure of another exemplary array substrate. As shown in FIG. 2, the array substrate includes a common electrode line 22, a first insulation layer 23, a second insulation layer 25, a third insulation layer 26, a fourth insulation layer 27, a first via D, a second via E, a connection electrode 28, and a transfer electrode 24 which are stacked on a base substrate 21. The first via D penetrates through the first insulation layer 23 and the second insulation layer 25, the second via E penetrates through the third insulation layer 26 and the fourth insulation layer 27, the common electrode line 22 is electrically connected with the transfer electrode 24 through the first via D, and the transfer electrode 24 is electrically connected with the connection electrode 28 through the second via E, thereby achieving an electrical connection between the common electrode line 22 and the connection electrode 28.

In this example, the common electrode line 22 is electrically connected with the transfer electrode 24 through the first via D, and the transfer electrode 24 is electrically connected with the connection electrode 28 through the second via E, thereby achieving the electrical connection between the common electrode line 22 and the connection electrode 28, which may improve problems of a deep etching depth and long etching time of a via. However, two vias need to be manufactured in the array substrate of this example, and one-time patterning process (i.e., a mask process) is added, thereby increasing manufacturing complexity of the array substrate and increasing a manufacturing cost.

In order to solve at least one of the above technical problems, an embodiment of the present disclosure provide a preparation method of an array substrate and the array substrate, which are further described in detail with reference to the drawings and specific implementation modes.

It should be noted that in this embodiment, a patterning process may only include a photolithography process, or include a photolithography process and an etching act, and at the same time may further include another process for forming a predetermined pattern such as printing and inkjet. The photolithography process refers to a process of forming a pattern by using photoresist, a mask plate, and an exposure machine, and the process includes film formation, exposure, development, and another process. A corresponding patterning process may be selected according to a structure formed in this embodiment.

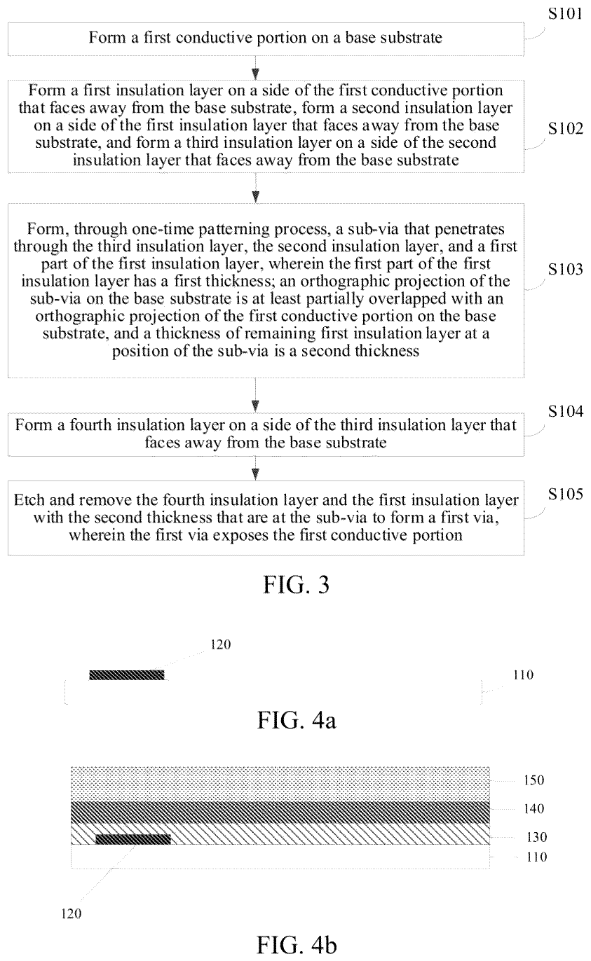

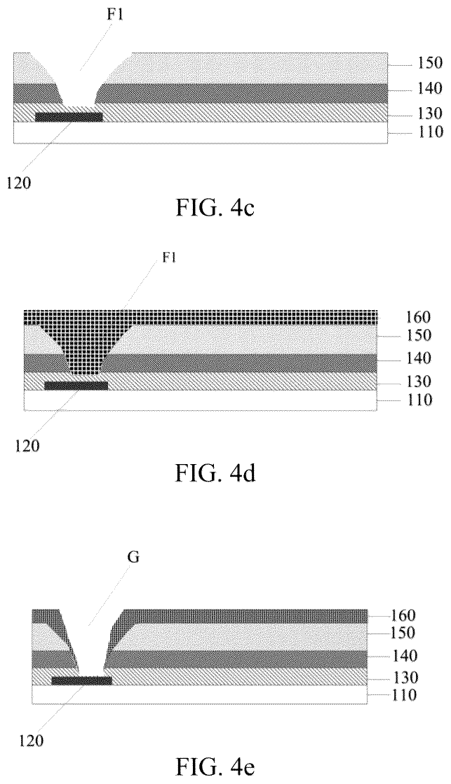

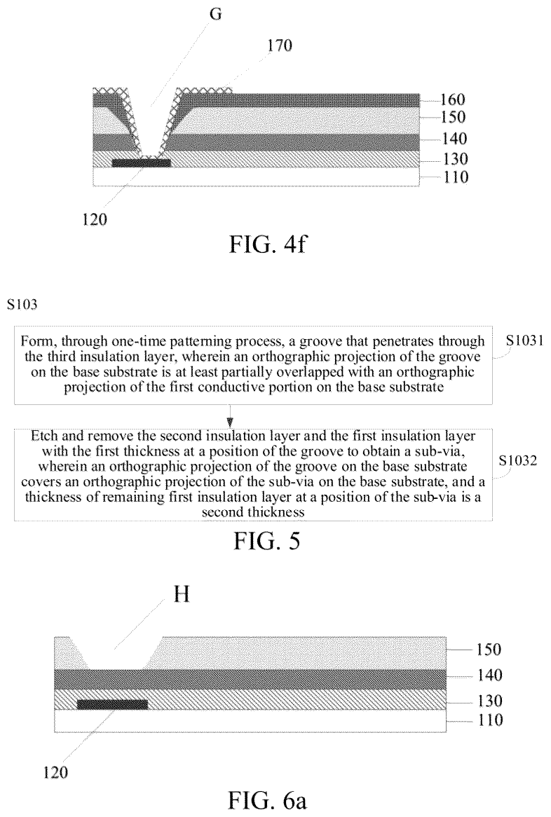

In a first aspect, an embodiment of the present disclosure provides a preparation method of an array substrate. FIG. 3 is a process flowchart of a preparation method of an array substrate according to an embodiment of the present disclosure; and FIGS. 4a to 4f are schematic diagrams of a structure of an array substrate in each act of the process flowchart shown in FIG. 3. As shown in FIGS. 3 to 4f, the preparation method of the array substrate includes following acts.
S101, forming a first conductive portion 120 on a base substrate 110.

Specifically, as shown in FIG. 4a, in this act, the base substrate 110 is made of a transparent material such as glass, resin, sapphire, quartz, and the like, and is pre-cleaned. A first conductive thin film is formed by using a sputtering mode, a thermal evaporation mode, a Plasma Enhanced Chemical Vapor Deposition (PECVD) mode, a Low Pressure Chemical Vapor Deposition (LPCVD) mode, an Atmospheric Pressure Chemical Vapor Deposition (APCVD) mode, or an Electron Cyclotron Resonance Chemical Vapor Deposition (ECR-CVD) mode, and photoresist coating, exposure, development, etching, and photoresist stripping are carried out on the first conductive thin film to form the first conductive portion 120, as shown in FIG. 4a.

A material of the first conductive portion 120 is not specifically limited. For example, the material of the first conductive portion 120 is a single layer or a multi-layer composite laminate formed of one or more of Molybdenum (Mo), a Molybdenum-Niobium (MoNb) alloy, Aluminum (Al), an Aluminum-Neodymium (AlNd) alloy, Titanium (Ti), and Copper (Cu), and is preferably a single layer or a multi-layer composite film composed of Mo, Al, or an alloy containing Mo and Al.
S102, forming a first insulation layer 130 on a side of the first conductive portion 120 that faces away from the base substrate 110, forming a second insulation layer 140 on a side of the first insulation layer 130 that faces away from the base substrate 110, and forming a third insulation layer 150 on a side of the second insulation layer 140 that faces away from the base substrate 110.

Specifically, as shown in FIG. 4b, the first insulation layer 130, the second insulation layer 140, and the third insulation layer 150 are sequentially formed on the side of the first conductive portion that faces away from the base substrate by using a preparation method such as thermal growth, atmospheric pressure chemical vapor deposition, low pressure chemical vapor deposition, plasma assisted chemical vapor deposition, and sputtering.

Materials of the first insulation layer 130, the second insulation layer 140, and the third insulation layer 150 may be selected as required and are not specifically limited herein, and may be, for example, Silicon Oxide (SiOx), Silicon Nitride (SiNx), Hafnium Oxide (HfOx), Silicon Oxynitride (SiON), Aluminum Oxide (AlOx), and the like.

S103, forming, through one-time patterning process, a sub-via F1 that penetrates through the third insulation layer 150, the second insulation layer 140, and a first part of the first insulation layer 130, wherein the first part of the first insulation layer 130 has a first thickness, an orthographic projection of the sub-via F1 on the base substrate 110 is at least partially overlapped with an orthographic projection of the first conductive portion 120 on the base substrate 110, and a thickness of remaining first insulation layer 130 at a position of the sub-via F1 is a second thickness.

Specifically, as shown in FIG. 4c, a layer of photoresist is coated on the third insulation layer 150. Photoresist may be coated by using spin coating, scraping coating, or roll coating. The photoresist coated on the third insulation layer 150 is exposed and developed to form a pattern of the photoresist. The first sub-via F1 that penetrates through the third insulation layer 150, the second insulation layer 140, and the first part of the first insulation layer 130 is formed through a first etching process by using the pattern of the photoresist as an etching mask. Then, the photoresist is removed.

For example, dry etching may be adopted for the first etching process. For example, Reactive Ion Etching (RIE), Ion Beam Etching (IBE), Inductively Coupled Plasma (ICP) etching, and another method may be adopted for dry etching. For example, an ICP etching technology may be used for the first etching process to perform etching. ICP etching has characteristics of small Direct Current (DC) Bias damage, a high etching rate, controllable ion density and ion energy, etc., which may shorten etching time and accurately control etching morphology.

For example, the ICP etching technology may be adopted and a mixed gas of NF₃ and O₂ may be used as an etching gas for the first etching process to perform etching. For example, by adjusting an etching parameter, a side wall of the sub-via may be smooth and a slope may be gentle, and the etching parameter may be, for example, a working pressure, a power, an etching gas flow amount, and an etching gas composition ratio of an ICP etching device.
S104, forming a fourth insulation layer 160 on a side of the third insulation layer 150 that faces away from the base substrate 110.

Specifically, as shown in FIG. 4d, in this act, the fourth insulation layer 160 is sequentially formed on a side of the third insulation layer that faces away from the base substrate by using a preparation method such as thermal growth, atmospheric pressure chemical vapor deposition, low pressure chemical vapor deposition, plasma assisted chemical vapor deposition, and sputtering.

A material of the fourth insulation layer 160 may be selected as required and is not specifically limited herein, and may be, for example, Silicon Oxide (SiOx), Silicon Nitride (SiNx), Hafnium Oxide (HfOx), Silicon Oxynitride (SiON), Aluminum Oxide (AlOx), and the like
S105, etching and removing the fourth insulation layer and the first insulation layer 130 with the second thickness at the first sub-via F1, to form a first via G, wherein the first via G exposes the first conductive portion 120.

Specifically, as shown in FIG. 4e, the first via G is formed by etching and removing the fourth insulation layer 160 and the first insulation layer 130 with the second thickness at the first sub-via F1 by using a second etching process, to form the first via G, and the first via G exposes the first conductive portion 120.

For example, dry etching may be adopted for the second etching process. For example, Reactive Ion Etching (RIE), Ion Beam Etching (IBE), Inductively Coupled Plasma (ICP) etching, and another method may be adopted for dry etching.

For example, an ICP etching technology may be adopted and a mixed gas of SF₆ and O₂ may be used as an etching gas for the second etching process to perform etching. An etching rate of SF₆ and O₂ is relatively high, which may shorten production time. In addition, SF₆ and O₂ may react with an insulation layer to generate a volatile gas that is discharged in time by a vacuum system, so that a residual foreign matter generated in the etching process may be removed in time, to prevent the residual foreign matter from affecting subsequent etching, and to ensure the insulation layer not to be polluted by the residual foreign matter at the same time. For example, by adjusting an etching parameter, a side wall of the first via may be smooth and a slope may be gentle, and the etching parameter may be, for example, a working pressure, a power, an etching gas flow amount, and an etching gas composition ratio of an ICP etching device.
S106, forming a first connection electrode 170 on a side of the fourth insulation layer 160 that faces away from the base substrate 110, wherein the first connection electrode 170 is electrically connected with the first conductive portion 120 through the first via G.

Specifically, as shown in FIG. 4f, the first connection electrode 170 is formed on the side of the fourth insulation layer 160 that faces away from the base substrate 110, and the first connection electrode 170 is electrically connected with the first conductive portion 120 through the first via G. For example, a metal thin film of a connection electrode is formed by using a sputtering mode, a thermal evaporation mode, a Plasma Enhanced Chemical Vapor Deposition (PECVD) mode, a Low Pressure Chemical Vapor Deposition (LPCVD) mode, an Atmospheric Pressure Chemical Vapor Deposition (APCVD) mode, or an Electron Cyclotron Resonance Chemical Vapor Deposition (ECR-CVD) mode. Thereafter, the first connection electrode 170 is formed through a first patterning process (film formation, exposure, development, wet etching, or dry etching) by using a Half Tone Mask (HTM) or a Gray Tone Mask (GTM). A material of the first connection electrode 170 is a single layer or a multi-layer composite laminate formed of one or more of Molybdenum (Mo), a Molybdenum-Niobium (MoNb) alloy, Aluminum (Al), an Aluminum-Neodymium (AlNd) alloy, Titanium (Ti), and Copper (Cu), and is preferably a single layer or multi-layer composite film composed of Mo, Al, or an alloy containing Mo and Al.

In this embodiment, preparation of a via is completed through two etching processes, compared with preparation of a via through a single etching process (the preparation method of the array substrate shown in FIG. 1), an etching depth, i.e., etching time is reduced, so that subsequent lapping of a metal within the via may be prevented from being affected by increase of a polymer within the via, thereby improving a product yield and quality of a display apparatus. At the same time, compared with the preparation method of the array substrate shown in FIG. 2, one via is reduced, that is, one MASK process is reduced, thereby reducing a preparation act and saving a cost.

In some embodiments, as shown in FIG. 5, the act S103, forming, through one-time patterning process, the first sub-via that penetrates through the third insulation layer, the second insulation layer, and the first part of the first insulation layer, specifically includes following acts.
S1031, forming, through one-time patterning process, a groove H formed by penetrating through the third insulation layer 150, wherein an orthographic projection of the groove H on the base substrate 110 is at least partially overlapped with an orthographic projection of the first conductive portion 120 on the base substrate 110.

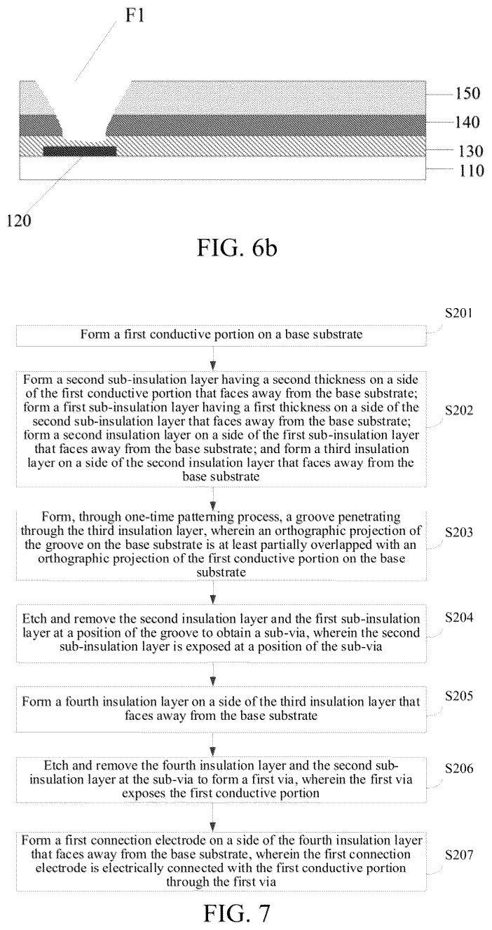

Specifically, as shown in FIG. 6a, the groove H formed by penetrating through the third insulation layer 150 is formed by using a first etching process. For example, a dry etching technology may be adopted and a mixed gas of NF₃ and O₂ may be used as an etching gas for the first etching process to perform etching.
S1032, etching and removing the second insulation layer 140 and the first insulation layer 130 with the first thickness at a position of the groove H to obtain the first sub-via F1, wherein an orthographic projection of the groove H on the base substrate 110 covers an orthographic projection of the first sub-via F1 on the base substrate 100, and a thickness of remaining first insulation layer 130 at a position of the first sub-via F1 is a second thickness.

Specifically, as shown in FIG. 6b, the second insulation layer 140 and the first insulation layer 130 with the first thickness at the position of the groove H are etched and removed by using a second etching process to obtain the first sub-via F1. For example, a dry etching technology may be adopted and a mixed gas of NF₃ and O₂ may be used as an etching gas for the first etching process to perform etching. By adjusting an etching parameter, a side wall of the first sub-via may be smooth and a slope may be gentle.

In this embodiment, the first sub-via is formed through two etching processes, etching time of the first sub-via is reduced, thereby preventing subsequent lapping of a metal in the via from being affected by increase of a polymer within the first sub-via, and further improving a product yield and quality of a display apparatus.

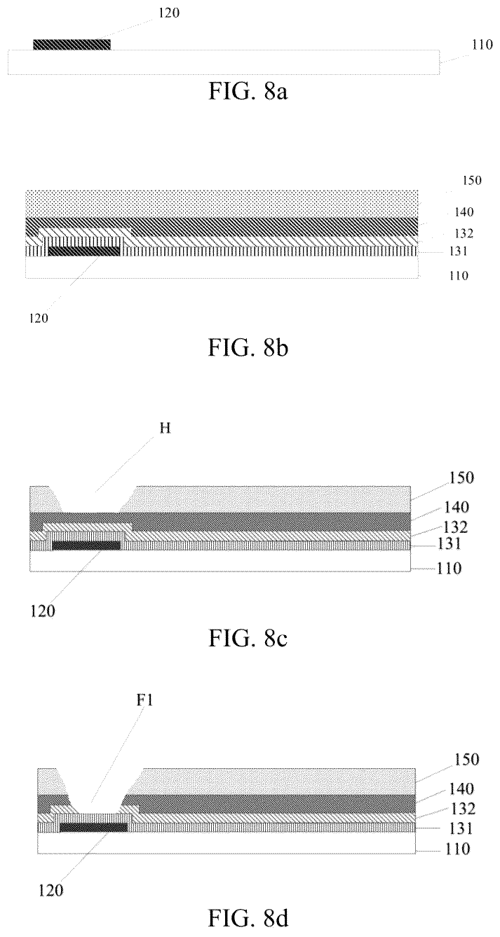

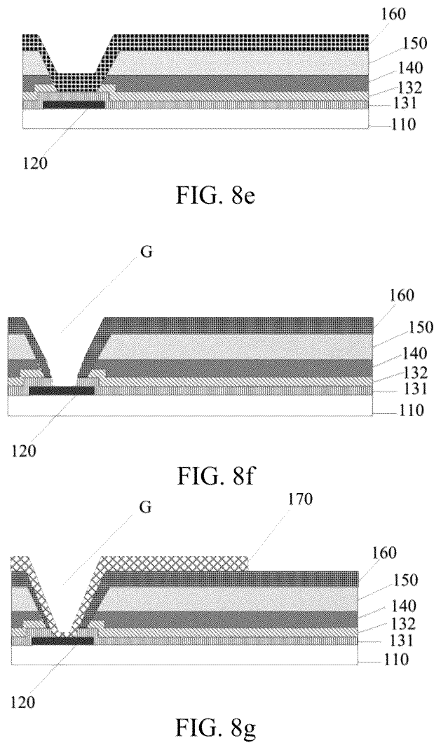

FIG. 7 is a process flowchart of another preparation method of an array substrate according to an embodiment of the present disclosure; and FIGS. 8a to 8f are schematic diagrams of a structure of an array substrate in each act shown in FIG. 7. As shown in FIGS. 7 to 8f, an embodiment of the present disclosure provides another preparation method of an array substrate, including following acts.
S201, as shown in FIG. 8a, forming a first conductive portion 120 on a base substrate 110. The act S201 is the same as the act S101 of the above embodiment and will not be repeated here.
S202, as shown in FIG. 8b, forming a second sub-insulation layer 131 having a second thickness on a side of the first conductive portion 120 that faces away from the base substrate 110; forming a first sub-insulation layer 132 having a first thickness on a side of the second sub-insulation layer 131 that faces away from the base substrate 110; forming a second insulation layer 140 on a side of the first sub-insulation layer 132 that faces away from the base substrate 110, and forming a third insulation layer 150 on a side of the second insulation layer 140 that faces away from the base substrate 110.

Specifically, in this act, the second sub-insulation layer 131, the first sub-insulation layer 132, the second insulation layer 140, and the third insulation layer 150 are sequentially formed on a side of the first conductive portion 120 that faces away from the base substrate by using a preparation method such as thermal growth, atmospheric pressure chemical vapor deposition, low pressure chemical vapor deposition, plasma assisted chemical vapor deposition, and sputtering.

Materials of the first sub-insulation layer 132, the second sub-insulation layer 131, the second insulation layer 140, and the third insulation layer 150 may be selected according to a situation, and will not be repeated here. Or, materials of the first sub-insulation layer 132 and the second insulation layer 131 are both silicon oxide, a material of the second sub-insulation layer 132 is silicon nitride, and a material of the third insulation layer 150 is an organic material.

S203, as shown in FIG. 8c, forming, through one-time patterning process, a groove H formed by penetrating through the third insulation layer 150, wherein an orthographic projection of the groove H on the base substrate 110 is at least partially overlapped with an orthographic projection of the first conductive portion 120 on the base substrate 110.

Specifically, a groove H formed by penetrating through the third insulation layer 150 is formed by using a first etching process. For example, for the first etching process, a dry etching technology may be adopted and a mixed gas of NF₃ and O₂ may be used as an etching gas to perform etching.

S204, as shown in FIG. 8d, etching and removing the second insulation layer and the first sub-insulation layer 132 at a position of the groove H to obtain a first sub-via F1, wherein an orthographic projection of the groove H on the base substrate 110 covers an orthographic projection of the first sub-via F1 on the base substrate 110, and the second sub-insulation layer 131 is exposed at a position of the first sub-via F1.

S205, as shown in FIG. 8e, forming a fourth insulation layer 160 on a side of the third insulation layer 150 that faces away from the base substrate 110. The act S205 is the same as the act S104 of the above embodiment, and will not be repeated here. Materials of the third insulation layer 150 and the fourth insulation layer 160 may be selected as required, and preferably, a material of the fourth insulation layer 160 is the same as that of the second sub-insulation layer 131, both of which are silicon nitride.

S206, as shown in FIG. 8f, etching and removing the fourth insulation layer 160 and the second sub-insulation layer 131 at the first sub-via F1 to form a first via G, wherein the first via G exposes the first conductive portion 120. The act S206 is the same as the act S105 of the above embodiment, and will not be repeated here.

S207, as shown in FIG. 8g, forming a first connection electrode 170 on a side of the fourth insulation layer 160 that faces away from the base substrate 110, wherein the first connection electrode 170 is electrically connected with the first conductive portion 120 through the first via G.

In this embodiment, preparation of the first via G is completed through multiple etching processes. Compared with preparation of a via through a single etching process (the preparation method of the array substrate shown in FIG. 1), a depth of single etching is reduced, and time of single etching is reduced, so that subsequent lapping of a metal within the first via G may be prevented from being affected by increase of a polymer within the first via G, thereby improving a product yield and quality of a display apparatus. At the same time, compared with the preparation method of the array substrate shown in FIG. 2, one via is reduced, that is, one MASK process is reduced, thereby reducing a preparation act and saving a cost.

Meanwhile, since materials of the second insulation layer 140 and the first sub-insulation layer 132 are the same, the first sub-insulation layer 132 may be etched synchronously when the second insulation layer 140 is etched, and since materials of the fourth insulation layer 160 and the second sub-insulation layer 131 are the same, the second sub-insulation layer 131 may be etched synchronously when the fourth insulation layer 160 is etched, thereby reducing etching time.

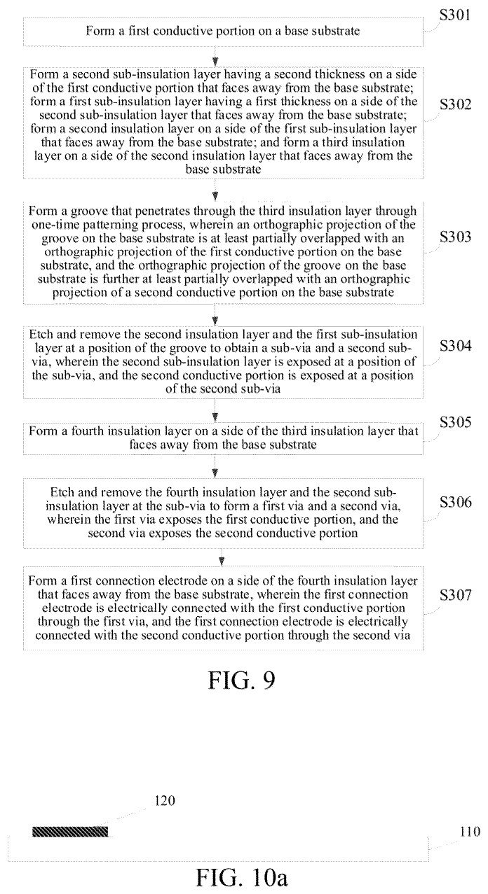

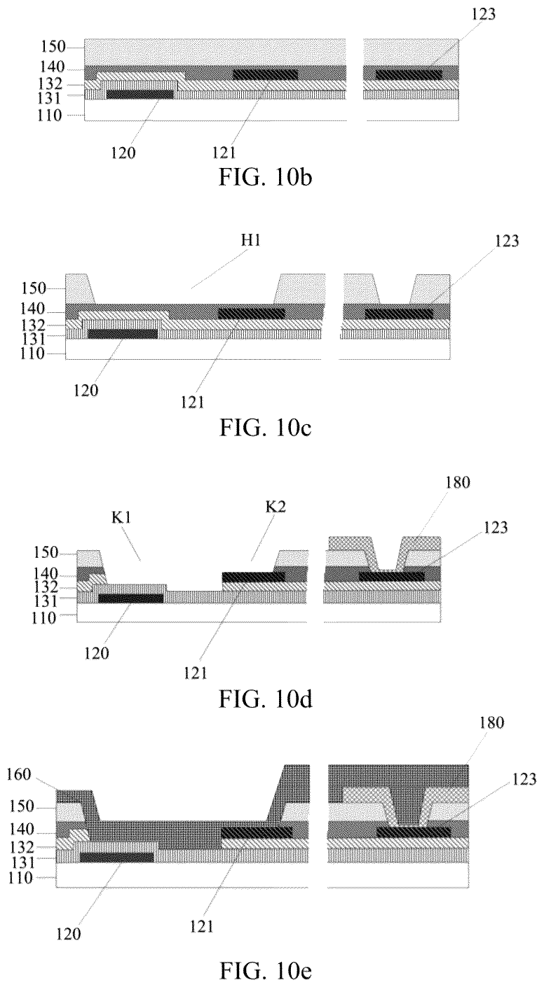

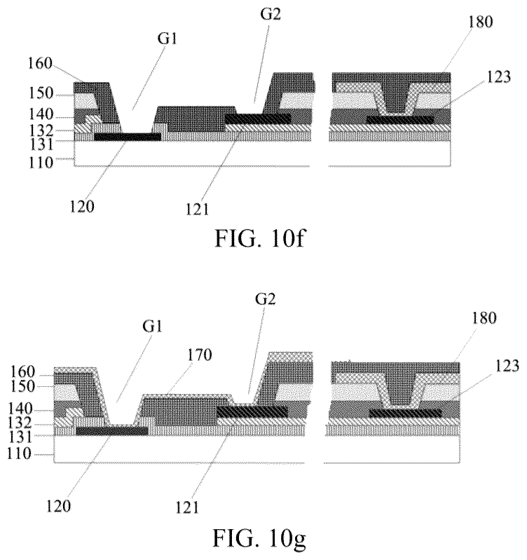

FIG. 9 is a process flowchart of yet another preparation method of an array substrate according to an embodiment of the present disclosure, and FIGS. 10a to 10g are schematic diagrams of a structure of an array substrate in each act shown in FIG. 9. As shown in FIGS. 9 to 10g, an embodiment of the present disclosure provides yet another preparation method of an array substrate, including following acts.
S301, as shown in FIG. 10a, forming a first conductive portion 120 on a base substrate 110.
S302, as shown in FIG. 10b, forming a second sub-insulation layer 131 having a second thickness on a side of the first conductive portion 120 that faces away from the base substrate 110; forming a first sub-insulation layer 132 having a first thickness on a side of the second sub-insulation layer 131 that faces away from the base substrate 110; forming a second conductive portion 121 on a side of the first sub-insulation layer 132 that faces away from the base substrate 110, forming a second insulation layer 140 on a side of the second conductive portion 121 that faces away from the base substrate 110, and forming a third insulation layer 150 on a side of the second insulation layer 140 that faces away from the base substrate 110.
S303, as shown in FIG. 10c, forming a groove H1 formed by penetrating through the third insulation layer 150 through one-time patterning process, wherein an orthographic projection of the groove H1 on the base substrate 110 is at least partially overlapped with an orthographic projection of the first conductive portion 120 on the base substrate 110, and the orthographic projection of the groove H1 on the base substrate 110 is further at least partially overlapped with an orthographic projection of the second conductive portion 121 on the base substrate 110.
S304, as shown in FIG. 10d, etching and removing the second insulation layer 140 and the first sub-insulation layer 132 at a position of the groove H1 to obtain a first sub-via K1 and a second sub-via K2, wherein the second sub-insulation layer 131 is exposed at a position of the first sub-via K1, and the second conductive portion 120 is exposed at a position of the second sub-via K2.
S305, as shown in FIG. 10e, forming a fourth insulation layer 160 on a side of the third insulation layer 150 that faces away from the base substrate 110.
S306, as shown in FIG. 10f, etching and removing the fourth insulation layer 160 and the second sub-insulation layer 131 at the first sub-via K1 to form a first via G1 and a second via G2, wherein the first via G1 exposes the first conductive portion 120, and the second via G2 exposes the second conductive portion 121.
S307, as shown in FIG. 10g, forming a first connection electrode 170 on a side of the fourth insulation layer 160 that faces away from the base substrate 110, wherein the first connection electrode 170 is electrically connected with the first conductive portion 120 through the first via G1, and the first connection electrode 170 is electrically connected with the second conductive portion 121 through the second via G2.

It should be noted that processes and materials used in this embodiment are the same as those in the above-mentioned embodiment, so they will not be repeated here.

In this embodiment, preparation of a via is completed through multiple etching processes. Compared with preparation of a via through a single etching process (the preparation method of the array substrate shown in FIG. 1), an etching depth of single etching is reduced, and etching time of the single etching is reduced, so that subsequent lapping of a metal within the first via G1 and the second via G2 may be prevented from being affected by increase of a polymer within the first via G1 and the second via G2, thereby improving a product yield and quality of a display apparatus.

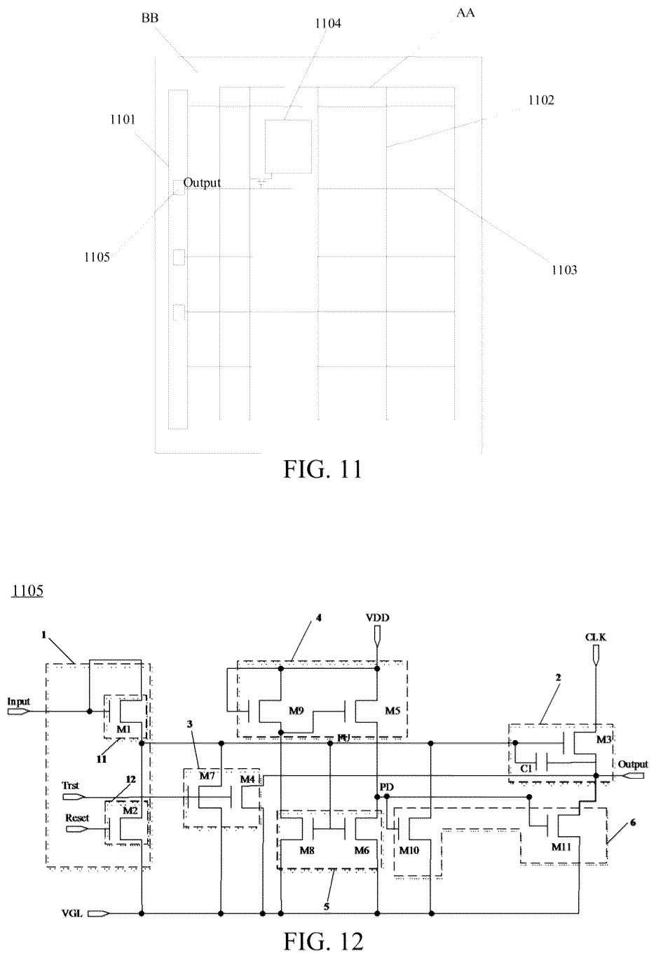

In some embodiments, FIG. 11 is a schematic diagram of a structure of an array substrate. As shown in FIG. 11, the array substrate includes a display region AA and a peripheral region BB surrounding the display region. The peripheral region BB is provided with a gate drive circuit 1101, and the gate drive circuit 1101 includes a plurality of shift registers 1105.

FIG. 12 is a circuit diagram of a shift register 1105. As shown in FIG. 12, the shift register 1105 includes an input circuit 1, an output circuit 2, a frame reset circuit 3, a pull-down control circuit 4, a pull-down circuit 5, and a first noise reduction circuit 6. A connection node between the input circuit 1, the output-output circuit 2, and the pull-down circuit 5 is a pull-up node PU; and a node between the pull-down control circuit 4 and the pull-down circuit 5 is a pull-down node PD. The input circuit 1 is configured to charge and reset the pull-up node PU; the output circuit 2 is configured to respond to a potential of the pull-up node PU and output a clock signal through a signal output terminal Output; the frame reset circuit 3 is configured to reset output of the pull-up node PU and the signal output terminal Output through a low-level signal in response to a reset signal in a blanking stage; the pull-down control circuit 4 is configured to respond to a first power supply voltage and control a potential of the pull-down node PD through the first power supply voltage; the pull-down circuit 5 is configured to respond to the pull-up node PU and pull down the potential of the pull-down node PD through a low-level signal; the first noise reduction circuit is configured to reduce a noise of the output of the pull-up node PU and the signal output terminal Output in response to the potential of the pull-down node PD.

Continuing with reference to FIG. 12, the input circuit 1 may include an input sub-circuit 11 and a reset sub-circuit 12, wherein the input sub-circuit 11 is configured to respond to an input signal and pre-charge the pull-up node PU through the input signal, and the reset sub-circuit 12 is configured to respond to a reset signal and reset the pull-up node PU through a low-level signal. As shown in FIG. 1, the input sub-circuit may include a first transistor M1. A source and a gate of the first transistor M1 are both connected with an input signal terminal Input, and a drain of the first transistor M1 is connected with the pull-up node PU. In this case, when a high-level signal is written into the input signal terminal Input, the first transistor M1 is turned on, and the pull-up node PU is pre-charged through the high-level signal written into the signal input terminal. The reset sub-circuit may include a second transistor M2. A source of the second transistor M2 is connected with the pull-up node PU, a drain of the second transistor M2 is connected with a low-level signal terminal VGL, and a gate of the second transistor M2 is connected with a reset signal terminal Reset. In this case, when a high-level signal is written into the reset signal terminal Reset, the second transistor M2 is turned on, and the pull-up node PU is pulled down and reset through the low-level signal of the low-level signal terminal VGL.

Referring to FIG. 12, the output circuit 2 in the shift register may include a third transistor M3 and a storage capacitor C1. A source of the third transistor M3 is connected with a clock signal terminal CLK, a drain of the third transistor M3 is connected with a signal output terminal Output, and a gate of the third transistor M3 is connected with the pull-up node PU. A first electrode plate of the storage capacitor C1 is connected with the pull-up node PU, and a second electrode plate of the storage capacitor C1 is connected with the signal output terminal Output. In this case, when the pull-up node PU is charged to a high-level signal, the storage capacitor C1 stores the high-level signal, meanwhile the third transistor M3 is turned on, and a clock signal inputted from the clock signal terminal CLK is outputted through a signal output.

Referring to FIG. 12, the frame reset circuit 3 in the shift register may include a fourth transistor M4 and a seventh transistor M7. A source of the fourth transistor M4 is connected with the signal output terminal Output, a drain of the fourth transistor M4 is connected with the low-level signal terminal VGL, and a gate of the fourth transistor M4 is connected with a reset signal terminal Trst. A source of the seventh transistor M7 is connected with the pull-up node PU, a drain of the seventh transistor M7 is connected with the low-level signal terminal VGL, and a gate of the seventh transistor M7 is connected with the reset signal terminal Trst. In this case, when a display stage of displaying one or more frames is finished and a blanking stage is entered, a high-level signal is written into the reset signal terminal Trst. At this time, the fourth transistor M4 and the seventh transistor M7 are turned on, and a low-level signal of the low-level signal terminal VGL resets the signal output terminal Output through the fourth transistor M4, and resets the pull-up node PU through the seventh transistor M7. The frame reset circuit 3 is disposed in the shift register, which may effectively prevent noises of the pull-up node PU and the signal output terminal Output in one frame of picture display from being transmitted to a next frame of displayed picture.

Referring to FIG. 12, the pull-down control circuit 4 in the shift register may include a fifth transistor M5 and a ninth transistor M9. A source of the fifth transistor M5 is connected with a first power supply voltage terminal VDD, a drain of the fifth transistor M5 is connected with the pull-down node PD, and a gate of the fifth transistor M5 is connected with a drain of the ninth transistor M9. A source and a gate of the ninth transistor M9 are connected with the first power supply voltage terminal VDD. In this case, a first power supply voltage of the first power supply voltage terminal VDD controls the fifth transistor M5 and the ninth transistor M9 to be turned on and pulls up the potential of the pull-down node PD.

Referring to FIG. 12, the pull-down circuit 5 in the shift register may include a sixth transistor M6 and an eighth transistor M8. A source of the sixth transistor M6 is connected with the pull-down node PD, a drain of the sixth transistor M6 is connected with the low-level signal terminal VGL, and a gate of the sixth transistor M6 is connected with the pull-up node PU. A source of the eighth transistor M8 is connected with the pull-down control circuit 4, a drain of the eighth transistor M8 is connected with the low-level signal terminal VGL, and a gate of the eighth transistor M8 is connected with the pull-up node PU. In this case, when the potential of the pull-up node PU is a high-level signal, both the sixth transistor M6 and the eighth transistor M8 are turned on, and a low-level signal of the low-level signal terminal VGL pulls down the potential of the pull-down node PD through the sixth transistor M6, and pulls down a potential of the pull-down control circuit 4 through the eighth transistor M8.

Referring to FIG. 12, the first noise reduction circuit 6 in the shift register may include a tenth transistor M10 and an eleventh transistor M11. A source of the tenth transistor M10 is connected with the pull-up node PU, a drain of the tenth transistor M10 is connected with the low-level signal terminal VGL, and a gate of the tenth transistor M10 is connected with the pull-down node PD. A source of the eleventh transistor M11 is connected with the signal output terminal Output, a drain of the eleventh transistor M11 is connected with the low-level signal terminal VGL, and a gate of the eleventh transistor M11 is connected with the pull-down node PD. In this case, when the pull-up node PD is at a high level, the tenth transistor M10 and the eleventh transistor M11 are turned on, the low-level signal of the low-level signal terminal VGL reduces a noise of output of the pull-up node PU through the tenth transistor M10, and reduces a noise of output of the output terminal Output through the tenth transistor M10.

As shown in FIG. 12, a gate of the pull-down control transistor M9 is electrically connected with a source. In the embodiment shown in FIG. 10g, the first conductive portion 120 may be the gate of the pull-down control transistor M9, the second conductive portion 121 may be the source of the pull-down control transistor M9, and the gate of the pull-down control transistor M9 is electrically connected with the source of the pull-down control transistor M9 through the first connection electrode 170.

It should be noted that this embodiment is described by taking a shift register circuit of 16T1C as an example. Of course, the shift register circuit may be of another type, which will not be specifically limited herein.

In this embodiment, preparation of a via is completed through multiple etching processes. Compared with preparation of a via through a single etching process (the preparation method of the array substrate shown in FIG. 1), an etching depth of single etching is reduced, and etching time of the single etching is reduced, so that subsequent lapping of a metal within the first via G1 and the second via G2 may be prevented from being affected by increase of a polymer within the first via G1 and the second via G2, thereby improving a product yield and quality of a display apparatus.

In some embodiments, as shown in FIG. 11, the array substrate includes a display region AA and a peripheral region BB surrounding the display region, and the array substrate further includes a gate line 1103 extending from the display region AA to the peripheral region BB, the peripheral region BB is provided with a gate drive circuit 1101, the gate drive circuit 1101 includes a plurality of shift registers 1105, wherein a signal output terminal Output of each shift register 1105 is electrically connected with the gate line 1103. This embodiment is described by taking a shift register 1105 shown in FIG. 12 as an example. As shown in FIG. 12, a drain of an output transistor M3 in the shift register is connected with a signal output terminal Output, and the signal output terminal Output is connected with the gate line 1103.

In the embodiment shown in FIG. 10g, the first conductive portion 120 may be the gate line 1103, and the second conductive portion 121 may be the signal output terminal Output of the gate drive circuit 1101, wherein the signal output terminal Output of the gate drive circuit 1101 is electrically connected with the gate line 1103 through the first connection electrode 170.

In this embodiment, preparation of a first via is completed through multiple etching processes. Compared with preparation of a via through a single etching process (the preparation method of the array substrate shown in FIG. 1), an etching depth of single etching is reduced, and etching time of the single etching is reduced, so that subsequent lapping of a metal within the first via G1 and the second via G2 may be prevented from being affected by increase of a polymer within the first via G1 and the second via G2, thereby improving a product yield and quality of a display apparatus.

In some embodiments, as shown in FIG. 11, the array substrate includes a plurality of gate lines 1103 and a plurality of data lines 1102 which are disposed in a cross way, and a plurality of sub-pixels, wherein a sub-pixel includes a thin film transistor, a pixel electrode, and a common electrode 1104. The gate line 1103 and a gate of the thin film transistor are also formed while the first conductive portion is formed; and the common electrode 1104 is also formed while the first connection electrode 170 is formed.

In some embodiments, the array substrate further includes a common electrode line, and the first conductive portion may also be used as the common electrode line.

In some embodiments, as shown in FIGS. 10a to 10g, it should be noted that the array substrate shown in FIGS. 10a to 10g is divided into a first portion and a second portion, wherein the first portion and the second portion are respectively in different sectional planes of the array substrate. In the second portion, as shown in FIGS. 10a to 10g, the preparation method of the array substrate further includes following acts: forming a third conductive portion 123 on a side of the first sub-insulation layer 132 that faces away from the base substrate 100; forming, through one-time patterning process, a third sub-via on the third insulation layer 150, wherein an orthographic projection of the third sub-via on the base substrate 100 is further at least partially overlapped with an orthographic projection of the third conductive portion 123 on the base substrate 100; etching and removing the second insulation layer 140 within the third sub-via to form a third via; and forming a second connection electrode layer on a side of the fourth insulation layer 140 that faces away from the base substrate 100, and forming a second connection electrode 180 through a patterning process, wherein the second connection electrode 180 is electrically connected with the third conductive portion 120 through the third via. In this embodiment, in a process of manufacturing the first via in region A, the third via in region B may be prepared simultaneously, thereby reducing a manufacturing act and saving a manufacturing cost.

In a second aspect, an embodiment of the present disclosure provides a preparation method of a display panel, including the preparation method of the array substrate as described above.

It may be understood that the above implementation modes are only exemplary implementation modes adopted for explaining a principle of the present disclosure. However, the present disclosure is not limited thereto. For those skilled in the art, various variations and improvements may be made without departing from the spirit and substance of the present disclosure, and these variations and improvements are also regarded as the protection scope of the present disclosure.

1. A preparation method of an array substrate, comprising:
forming a first conductive portion on a base substrate;
forming a first insulation layer on a side of the first conductive portion that faces away from the base substrate, forming a second insulation layer on a side of the first insulation layer that faces away from the base substrate, and forming a third insulation layer on a side of the second insulation layer that faces away from the base substrate;
forming, through one-time patterning process, a first sub-via that penetrates through the third insulation layer, the second insulation layer, and a first part of the first insulation layer, wherein the first part of the first insulation layer has a first thickness; an orthographic projection of the first sub-via on the base substrate is at least partially overlapped with an orthographic projection of the first conductive portion on the base substrate, and a thickness of remaining first insulation layer at a position of the first sub-via is a second thickness;
forming a fourth insulation layer on a side of the third insulation layer that faces away from the base substrate;
etching and removing the fourth insulation layer and the first insulation layer with the second thickness that are at the first sub-via to form a first via, wherein the first via exposes the first conductive portion; and
forming a first connection electrode on a side of the fourth insulation layer that faces away from the base substrate, wherein the first connection electrode is electrically connected with the first conductive portion through the first via.

2. The preparation method of the array substrate according to claim 1, wherein the act of forming, through one-time patterning process, the first sub-via that penetrates through the third insulation layer, the second insulation layer, and the first part of the first insulation layer specifically comprises:
forming, through one-time patterning process, a groove penetrating through the third insulation layer, wherein an orthographic projection of the groove on the base substrate is at least partially overlapped with the orthographic projection of the first conductive portion on the base substrate; and
etching and removing the second insulation layer and the first insulation layer with the first thickness at a position of the groove to obtain a first sub-via, wherein the orthographic projection of the groove on the base substrate covers the orthographic projection of the first sub-via on the base substrate, and the thickness of the remaining first insulation layer at the position of the first sub-via is the second thickness.

3. The preparation method of the array substrate according to claim 2, wherein the act of forming the first insulation layer on the side of the first conductive portion that faces away from the base substrate specifically comprises:
forming a second sub-insulation layer having the second thickness on a side of the first conductive portion that faces away from the base substrate; and
forming a first sub-insulation layer having the first thickness on a side of the second sub-insulation layer that faces away from the base substrate;
the act of etching and removing the second insulation layer and the first insulation layer with the first thickness at the position of the groove to obtain the first sub-via specifically comprises:
etching and removing the second insulation layer and the first sub-insulation layer at the position of the groove to obtain the first sub-via; and
the act of etching and removing the fourth insulation layer and the first insulation layer with the second thickness at the first sub-via to form the first via comprises:
etching and removing the fourth insulation layer and the second sub-insulation layer at the first sub-via to form the first via.

4. The preparation method of the array substrate according to claim 3, wherein a material of the first sub-insulation layer comprises silicon oxide, and materials of the second sub-insulation layer and the fourth insulation layer comprise silicon nitride.

5. The preparation method of the array substrate according to claim 3, wherein between the act of forming the first insulation layer and the act of forming the second insulation layer, the method further comprises: forming a second conductive portion on a side of the first sub-insulation layer that faces away from the base substrate;
forming, through one-time patterning process, the groove on the third insulation layer, wherein the orthographic projection of the groove on the base substrate is further at least partially overlapped with an orthographic projection of the second conductive portion on the base substrate; and
etching and removing the second insulation layer and the first sub-insulation layer at the position of the groove to obtain a second sub-via; and
after the act of forming the fourth insulation layer on the side of the third insulation layer that faces away from the base substrate, the method further comprises:
etching and removing the fourth insulation layer and the second sub-insulation layer at the second sub-via to form a second via, wherein the second via exposes the second conductive portion; and
forming a first connection electrode on a side of the fourth insulation layer that faces away from the base substrate, wherein the first connection electrode is further electrically connected with the second conductive portion through the second via.

6. The preparation method of the array substrate according to claim 5, wherein the array substrate comprises a display region and a peripheral region surrounding the display region, the peripheral region is provided with a gate drive circuit, the gate drive circuit comprises shift registers, each shift register comprises a plurality of thin film transistors, the plurality of thin film transistors at least comprise a pull-down control transistor, a gate of the pull-down control transistor is electrically connected with a source;
wherein the first conductive portion is the gate of the pull-down control transistor, and the second conductive portion is the source of the pull-down control transistor.

7. The preparation method of the array substrate according to claim 5, wherein the array substrate comprises a display region and a peripheral region surrounding the display region, the array substrate further comprises a gate line extending from the display region to the peripheral region, the peripheral region is provided with a gate drive circuit, the gate drive circuit comprises a plurality of shift registers, each shift register comprises a plurality of thin film transistors, the plurality of thin film transistors at least comprise an output transistor, a drain of the output transistor is connected with a signal output terminal, and the signal output terminal is connected with the gate line;
wherein the first conductive portion is the gate line, and the second conductive portion is the signal output terminal.

8. The preparation method of the array substrate according to claim 1, wherein the array substrate comprises a plurality of gate lines and a plurality of data lines which are disposed in a cross way, and a plurality of sub-pixels, wherein a sub-pixel comprises a thin film transistor, a pixel electrode, and a common electrode;
the gate lines and a gate of the thin film transistor are also formed while the first conductive portion is formed; and
the common electrode is also formed while the first connection electrode is formed.

9. The preparation method of the array substrate according to claim 8, wherein the array substrate further comprises a common electrode line, and the first conductive portion serves as the common electrode line.

10. The preparation method of the array substrate according to claim 5, further comprising:
further forming a third conductive portion on a side of the first sub-insulation layer that faces away from the base substrate;
further forming, through one-time patterning process, a third sub-via on the third insulation layer, wherein an orthographic projection of the third sub-via on the base substrate is further at least partially overlapped with an orthographic projection of the third conductive portion on the base substrate;
etching and removing the second insulation layer within the third sub-via to form a third via; and
forming a second connection electrode layer on a side of the fourth insulation layer that faces away from the base substrate, and forming a second connection electrode through a patterning process, wherein the second connection electrode is electrically connected with the third conductive portion through the third via.

11. The preparation method of the array substrate according to claim 4, wherein the act of etching and removing the second insulation layer and the first sub-insulation layer at the position of the first sub-via to obtain the second sub-via specifically comprises:
etching and removing the second insulation layer and the first sub-insulation layer that are at the position of the first sub-via through dry etching to obtain the second sub-via.

12. The preparation method of the array substrate according to claim 11, wherein a gas used for the dry etching comprises NF₃ and O₂.

13. The preparation method of the array substrate according to claim 4, wherein the act of etching and removing the fourth insulation layer and the second sub-insulation layer at the second sub-via to form the first via specifically comprises:
etching and removing the fourth insulation layer and the second sub-insulation layer at the second sub-via through dry etching to form the first via, wherein an etching gas comprises SF₆ and O₂.

14. A preparation method of a display panel, comprising a preparation method of an array substrate according to claim 1.

15. An array substrate, comprising:
a base substrate;
a first conductive portion;
a first insulation layer formed on a side of the first conductive portion that faces away from the base substrate, a second insulation layer formed on a side of the first insulation layer that faces away from the base substrate, and a third insulation layer formed on a side of the second insulation layer that faces away from the base substrate;
a first sub-via penetrating through the third insulation layer, the second insulation layer, and a first part of the first insulation layer, wherein the first part of the first insulation layer has a first thickness, an orthographic projection of the first sub-via on the base substrate is at least partially overlapped with an orthographic projection of the first conductive portion on the base substrate, and a thickness of remaining first insulation layer at a position of the first sub-via is a second thickness;
a fourth insulation layer formed on a side of the third insulation layer that faces away from the base substrate;
a first via, wherein the first via exposes the first conductive portion; and
a first connection electrode formed on a side of the fourth insulation layer that faces away from the base substrate, wherein the first connection electrode is electrically connected with the first conductive portion through the first via.

16. The array substrate according to claim 15, further comprising:
a second sub-insulation layer having the second thickness formed on a side of the first conductive portion that faces away from the base substrate; and
a first sub-insulation layer having the first thickness formed on a side of the second sub-insulation layer that faces away from the base substrate.

17. The array substrate according to claim 16, further comprising: a second sub-via penetrating through the fourth insulation layer and the second sub-insulation layer.

18. The array substrate according to claim 16, wherein a material of the first sub-insulation layer comprises silicon oxide, and materials of the second sub-insulation layer and the fourth insulation layer comprise silicon nitride.

19. The array substrate according to claim 15, wherein a material of the third insulation layer is an organic material.

20. The array substrate according to claim 16, further comprising: a second conductive portion formed on a side of the first sub-insulation layer that faces away from the base substrate; and a second via, wherein the second via exposes the second conductive portion;
wherein the first connection electrode is further electrically connected with the second conductive portion through the second via.
